(19) United States
(12) Patent Application Publication
(10) Pub. No.: US 2022/0066595 A1
(43) Pub. Date: Mar. 3, 2022

(54) TOUCH DISPLAY PANEL, MANUFACTURING METHOD THEREFOR AND ELECTRONIC DEVICE

(71) Applicant: SHENZHEN ROYOLE TECHNOLOGIES CO., LTD., Shenzhen (CN)

(72) Inventors: Jiahao KANG, Shenzhen (CN); Tina TSONG, Shenzhen (CN); Kumar Gupta AMIT, Shenzhen (CN); Ze YUAN, Shenzhen (CN)

(21) Appl. No.: 17/412,371

(22) Filed: Aug. 26, 2021

(30) Foreign Application Priority Data
Aug. 26, 2020 (CN) 202010872095.1

(51) Int. Cl. G06F 3/044; G06F 3/041; H01L 27/32

(52) U.S. Cl. CPC G06F 3/0446; G06F 3/04164; H01L 27/323; H01L 2227/323; H01L 27/3272; H01L 27/3276; G06F 2203/04103; H01L 27/3246

(57) ABSTRACT

The present application provides a touch display panel, a manufacturing method therefor and an electronic device. The touch display panel includes: a substrate; a light-emitting unit layer, where the light-emitting unit layer is located on one side of the substrate, and includes multiple cathode metal layers; and multiple touch induction electrodes arranged in an array, where the touch induction electrodes and the cathode metal layers are arranged at the same layer and insulated from each other, each of the touch induction electrodes is provided with at least one first through hole, a clearance is formed between adjacent two of the touch induction electrodes, and the cathode metal layers are arranged in the first through holes, or the clearance, or both. The touch display panel in the present application integrates a touch function into a display panel, so the touch display panel has a higher integration level and a smaller thickness.

### TECHNICAL FIELD

The present application relates to the field of touch display, and in particular, to a touch display panel, a manufacturing method therefor and an electronic device.

### BACKGROUND

With the development of flexible display technologies, touch screens are required to be as integrated and miniaturized as possible. At present, most of self-capacitive touch display screens are in add-on and on-cell modes and have disadvantages of large thickness, complex structure, a large number of adhesive structures and processes and high preparation cost. In addition, there are also disadvantages that are not conducive to bending of the screens and further integration and miniaturization of an electronic device.

### SUMMARY

In view of the problems, an embodiment of the present application provides a touch display panel. The touch display panel integrates a touch function into a display panel, so that the touch display panel has a higher integration level and a smaller thickness.

In addition, the present application further provides an electronic device.

In addition, the present application further provides a manufacturing method for a touch display panel.

The touch display panel according to the embodiment of the present application includes:

a substrate;

a light-emitting unit layer, where the light-emitting unit layer is located on one side of the substrate, and includes multiple cathode metal layers; and multiple touch induction electrodes arranged in an array, where the touch induction electrodes and the cathode metal layers are arranged at the same layer and insulated from each other, each of the touch induction electrodes is provided with at least one first through hole, a clearance is formed between adjacent two of the touch induction electrodes, and the cathode metal layers are arranged in the first through holes, or the clearance, or both.

Optionally, the cathode metal layers located in the first through holes are surrounded by the touch induction electrodes and are spaced from the touch induction electrodes by a gap or an insulating part.

Optionally, the touch display panel further includes multiple insulating spacers, where the spacers are located in the first through holes to space the cathode metal layers from the touch induction electrodes, and an area of a surface of each of the spacers that is adjacent to the substrate is smaller than an area of a surface of the spacer that faces away from the substrate.

Optionally, the at least one first through hole is spaced from one another, and one cathode metal layer is arranged in each of the first through holes.

Optionally, the cathode metal layers and the touch induction electrodes are staggered.

Optionally, the cathode metal layers each include multiple electrically-connected electrode strings, and the touch induction electrodes each are arranged between adjacent electrode strings.

Optionally, the first through holes communicate with the clearance, one of the electrode strings is arranged in each of the first through holes, and each of the electrode strings includes at least one electrically-connected sub-cathode.

Optionally, each of the touch induction electrodes includes a first touch part and multiple spaced second touch parts, and the first touch part is connected to each of the second touch parts; and the first through holes are formed between the multiple second touch parts.

Optionally, the touch display panel further includes multiple touch signal lines, where the touch signal lines are electrically connected to the touch induction electrodes; the touch signal lines and the cathode metal layers are arranged at the same layer and insulated from each other, and the touch signal lines are located in the clearance.

Optionally, the touch display panel further includes multiple touch signal lines, where the touch signal lines are electrically connected to the touch induction electrodes, the touch signal lines and the touch induction electrodes are arranged at different layers, and an insulating layer is arranged between the touch signal lines and the touch induction electrodes; the insulating layer is provided with a second through hole, and the touch signal lines are electrically connected to the touch induction electrodes by filling the second through hole with a conductive material.

Optionally, the light-emitting unit layer further includes multiple anodes arranged in an array, the anodes are located between the substrate and the cathode metal layers, and the touch signal lines and the anodes are arranged at the same layer and insulated from each other.

Optionally, the touch display panel further includes metal wires, where the touch signal lines and the metal wires are arranged at the same layer and insulated from each other.

Optionally, the touch display panel further includes a source and a drain, where the source and the drain are spaced at the same layer and insulated from each other, and the source and the drain are located between the substrate and light-emitting units; and the touch signal lines are arranged at the same layer as the source and the drain and insulated from the source and the drain.

Optionally, the touch display panel further includes a gate, where the gate is located between the substrate and the light-emitting units, and the touch signal lines and the gate are arranged at the same layer and insulated from each other.

Optionally, the touch display panel further includes a light shielding layer, where the light shielding layer is located on a surface of the substrate that faces the light-emitting units, and the touch signal lines and the light shielding layer are arranged at the same layer and insulated from each other.

Optionally, the touch display panel further includes multiple cathode lines, where the cathode lines each are electrically connected to at least one of the cathode metal layers; and the cathode lines are located in the first through holes, or the clearance, or both.

Optionally, the touch display panel further includes multiple cathode lines, where the cathode lines each are electrically connected to at least one of the cathode metal layers; the cathode lines and the cathode metal layers are arranged at different layers, and an insulating layer is arranged between the cathode lines and the cathode metal layers; the insulating layer is provided with a third through hole, and the cathode lines are electrically connected to the cathode metal layers by filling the third through hole with a conductive material.

Optionally, the light-emitting unit layer further includes multiple anodes arranged in an array, the anodes are located between the substrate and the cathode metal layers, and the cathode lines and the anodes are arranged at the same layer and insulated from each other.

Optionally, the touch display panel further includes metal wires, where the cathode lines and the metal wires are arranged at the same layer and insulated from each other.

Optionally, the touch display panel includes a source and a drain, where the source and the drain are spaced at the same layer and insulated from each other, and the source and the drain are located between the substrate and the light-emitting units; and the cathode lines are arranged at the same layer as the source and the drain and insulated from the source and the drain.

Optionally, the touch display panel further includes a gate, where the gate is located between the substrate and the light-emitting units, and the cathode lines and the gate are arranged at the same layer and insulated from each other.

Optionally, the touch display panel further includes a light shielding layer, where the light shielding layer is located on a surface of the substrate that faces the light-emitting units, and the cathode lines and the light shielding layer are arranged at the same layer and insulated from each other.

Optionally, the touch display panel further includes multiple display signal lines, where the display signal lines are opposite to the clearance.

Optionally, the display signal lines each are a display data signal line or a display scanning signal line.

Optionally, the cathode metal layers are connected to a low-level signal, and the touch induction electrodes are connected to a touch signal.

Based on the same invention concept, the present application further provides an electronic device, including:

a device body; and

the above-mentioned touch display panel, where the touch display panel is arranged on the device body.

Based on the same invention concept, the present application further provides a manufacturing method for a touch display panel, including:

forming a driver layer on one side of a substrate, and forming a light-emitting structure layer on a side of the driver layer that faces away from the substrate; and

forming cathode metal layers and touch induction electrodes on the light-emitting structure layer, where the touch induction electrodes and the cathode metal layers are arranged at the same layer and insulated from each other.

Optionally, the cathode metal layers and the touch induction electrodes are formed in the same process.

Optionally, the forming cathode metal layers and touch induction electrodes on the light-emitting structure layer specifically includes:

forming spacers on the light-emitting structure layer; and

forming metal layers on the light-emitting structure layer and the spacers, where the metal layers are spaced by the spacers in a forming process to form the cathode metal layers and the touch induction electrodes, respectively.

Optionally, an area of a surface of each of the spacers that is adjacent to the substrate is smaller than an area of a surface of the spacer that faces away from the substrate.

Optionally, the metal layers formed on the spacers are spaced from the cathode metal layers and the touch induction electrodes formed on the light-emitting structure layer, respectively.

Optionally, the forming a driver layer on one side of the substrate specifically includes:

forming drive circuits and metal wires on the side of the substrate, where the drive circuits each includes a source, a drain and a gate, or the drive circuits each includes a source, a drain, a gate and a light shielding layer, the metal wires are arranged at the same layer as and insulated from the source, the drain, the gate and the light shielding layer, respectively, and the metal wires are touch signal lines;

forming an insulating layer on the metal wires; and

forming a second through hole in the insulating layer, and filling the second through hole with a conductive material.

Optionally, the forming a driver layer on one side of the substrate specifically includes:

forming drive circuits and metal wires on the side of the substrate, where the drive circuits each includes a source, a drain and a gate, or the drive circuits each includes a source, a drain, a gate and a light shielding layer, the metal wires are arranged at the same layer as and insulated from the source, the drain, the gate and the light shielding layer, and the metal wires are cathode lines;

forming an insulating layer on the metal wires; and

forming a third through hole in the insulating layer, and filling the third through hole with a conductive material.

Optionally, the forming a light-emitting structure layer on a side of the driver layer that faces away from the substrate specifically includes:

forming multiple anodes arranged in an array on the side of the driver layer that faces away from the substrate;

forming a pixel definition layer on the multiple anodes and the side of the driver layer that faces away from the substrate, and forming multiple openings at positions in the pixel definition layer that correspond to the multiple anodes; and

forming multiple light-emitting parts arranged in an array in the multiple openings, respectively.

Optionally, the forming a light-emitting structure layer on a side of the driver layer that faces away from the substrate specifically further includes:

simultaneously forming multiple touch signal lines in the process of forming the multiple anodes arranged in an array, where the multiple touch signal lines and the anodes are arranged at the same layer and insulated from each other; and

forming the multiple touch induction electrodes further includes:

electrically connecting the touch induction electrodes to the touch signal lines.

Optionally, the forming a light-emitting structure layer on a side of the driver layer that faces away from the substrate specifically further includes:

simultaneously forming multiple cathode lines in the process of forming the multiple anodes arranged in an array, where the multiple cathode lines and the anodes are arranged at the same layer and insulated from each other; and

forming the multiple cathode metal layers further includes:

electrically connecting the cathode metal layers to the cathode lines.

In the touch display panel according to the present application, the cathode metal layers and the touch induction electrodes of the light-emitting unit layer are arranged at the same layer, and a touch panel is integrated into a display panel, so that the touch display panel has a higher integration level and a smaller thickness.

### BRIEF DESCRIPTION OF DRAWINGS

To illustrate structural features and functions of the present application more clearly, the following detailed description will be provided with reference to the accompanying drawings and specific embodiments.

FIG. 1 is a schematic structural diagram illustrating a touch display panel according to an embodiment of the present application;

FIG. 2 is a schematic structural diagram illustrating touch induction electrodes and cathode metal layers of a touch display panel according to an embodiment of the present application;

FIG. 3 is a schematic structural diagram illustrating touch induction electrodes and cathode metal layers of a touch display panel according to another embodiment of the present application;

FIG. 4 is a schematic structural diagram illustrating a touch display panel according to another embodiment of the present application;

FIG. 5 is a schematic structural diagram illustrating spacers according to an embodiment of the present application;

FIG. 6 is a schematic structural diagram illustrating a touch display panel according to still another embodiment of the present application;

FIG. 7 is a schematic structural diagram illustrating a touch display panel according to yet another embodiment of the present application;

FIG. 8 is a schematic structural diagram illustrating touch induction electrodes and touch signal lines of a touch display panel according to an embodiment of the present application;

FIG. 9 is a schematic structural diagram illustrating a touch display panel according to still yet another embodiment of the present application;

FIG. 10 is a schematic structural diagram illustrating a touch display panel according to a further embodiment of the present application;

FIG. 11 is a schematic structural diagram illustrating a touch display panel according to a still further embodiment of the present application;

FIG. 12 is a schematic structural diagram illustrating a touch display panel according to a yet further embodiment of the present application;

FIG. 13 is a schematic structural diagram illustrating touch induction electrodes and display signal lines according to an embodiment of the present application;

FIG. 14 is a schematic structural diagram illustrating an electronic device according to an embodiment of the present application; and

FIG. 15 is a schematic diagram illustrating a manufacturing process for a touch display panel according to an embodiment of the present application.

### DESCRIPTION OF EMBODIMENTS

The technical solutions in the embodiments of the present application will be clearly and completely described below with reference to the accompanying drawings in the embodiments of the present application. Apparently, the described embodiments are merely some rather than all of the embodiments of the present application. All other embodiments obtained by a person of ordinary skill in the art based on the embodiments of the present application without creative efforts shall fall within the protection scope of the present application.

A touch display panel 100 is a display panel integrating a touch function and a display function. Touch screens roughly fall into four types: infrared touch screens, resistive touch screens, surface acoustic wave touch screens and capacitive touch screens. Capacitive touch screens fall into self-capacitive touch screens and mutual capacitive touch screens.

A self-capacitive touch screen is implemented by using a transparent conductive material (such as indium tin oxide (ITO)) to prepare an array of horizontal and vertical electrodes on a surface of glass. These horizontal and vertical electrodes separately form capacitors with the ground. When a finger touches the capacitive screen, a capacitance of the finger will be superimposed on a capacitance of a screen body to increase the capacitance of the screen body.

A mutual capacitive touch screen is implemented by using two metals or metal oxide materials to form a set of parallel electrode patterns (at the same layer or different layers). Because a distance between two electrodes is very close, a capacitor is formed. When a finger touches the corresponding electrode, a capacitance between the two electrodes changes.

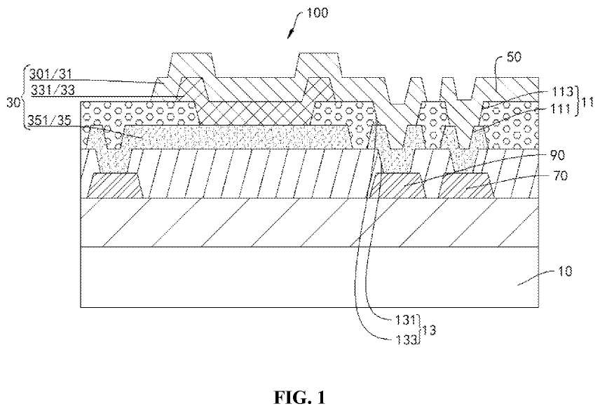

Referring to FIG. 1 to FIG. 3, the touch display panel 100 according to an embodiment of the present application includes: a substrate 10; a light-emitting unit layer 30, where the light-emitting unit layer 30 is located on one side of the substrate 10 and includes multiple cathode metal layers 31, and the cathode metal layers 31 each are configured to connect to a display drive signal, for example, connect to a low-level signal; and multiple touch induction electrodes 50 arranged in an array, where the touch induction electrodes 50 and the cathode metal layers 31 are arranged at the same layer and insulated from each other, and the touch induction electrodes 50 each are configured to connect to a touch signal, each of the touch induction electrodes 50 is provided with at least one first through hole 51, a clearance 53 is formed between adjacent two of the touch induction electrodes 50, and the cathode metal layers 31 are arranged in the first through holes 51, or the clearance 53, or both.

Optionally, the substrate 10 may be a glass substrate, or a substrate implemented by depositing a polyimide (PI) flexible substrate on a glass substrate, or the like.

Specifically, the light-emitting unit layer 30 includes the cathode metal layers 31, a light-emitting layer 33 and an anode layer 35 that are stacked in sequence. The cathode metal layers 31 each include at least one electrically-connected sub-cathode 301. The light-emitting layer 33 includes light-emitting parts 331 arranged in an array. One light-emitting part 331 corresponds to one sub-cathode 301. Each of the light-emitting parts 331 forms one sub-pixel. Three adjacent sub-pixels that can emit red, blue and green light respectively are formed in one pixel. A color and brightness of the pixel can be adjusted by controlling proportions of the red, blue and green light of the three sub-pixels. The anode layer 35 is disposed adjacent to the substrate 10, the anode layer 35 includes multiple anodes 351 arranged in an array, and one anode 351 corresponds to one light-emitting part 331.

Optionally, the cathode metal layers 31 and the touch induction electrodes 50 are formed in the same process. That is, the cathode metal layers 31 and the touch induction electrodes 50 are formed in the same process or step, for example, formed by splitting (such as etching) the same metal layer.

In the touch display panel 100 according to the present application, the cathode metal layers 31 and the touch induction electrodes 50 of the light-emitting unit layer 30 are arranged at the same layer, and a touch panel is integrated into a display panel, so that the touch display panel 100 has a higher integration level and a smaller thickness. In addition, the cathode metal layers 31 are not a whole metal, which improves the transparency of the entire touch display panel 100, reduces the reflection of ambient light by the cathode metal layer 31, and improves the display effect of the touch display panel 100.

Referring to FIG. 2 to FIG. 4, in some embodiments, the cathode metal layers 31 located in the first through holes 51 are surrounded by the touch induction electrodes 50 and are spaced from the touch induction electrodes 50 by a gap or an insulating part. That is, the cathode metal layers 31 located in the first through holes 51 and the touch induction electrodes 50 are spaced and insulated from each other. The cathode metal layers 31 and the touch induction electrodes 50 may be spaced and insulated from each other by the gap, or by arranging the insulating part.

Referring to FIG. 2, at least one first through hole 51 is spaced from one another, and one cathode metal layer 31 is arranged in each of the first through holes 51.

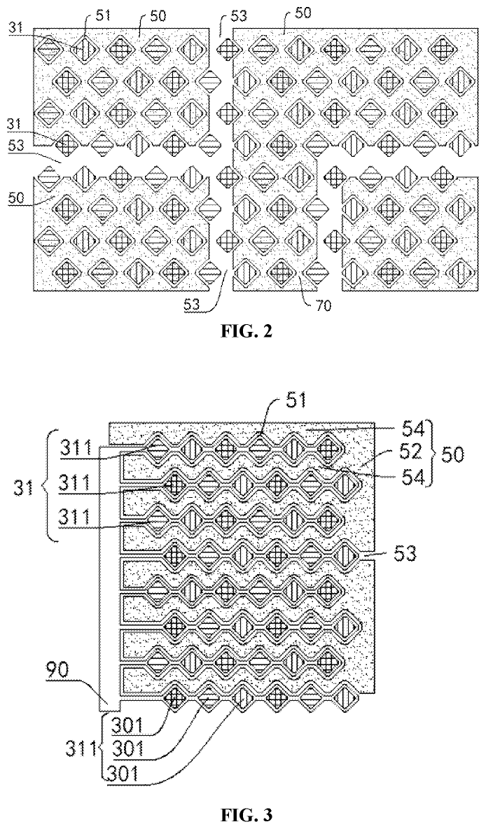

Referring to FIG. 3, in some embodiments, the cathode metal layers 31 and the touch induction electrodes 50 are staggered.

Optionally, in some embodiments, the cathode metal layers 31 each include multiple electrically-connected electrode strings 311, and the touch induction electrodes 50 each are arranged between adjacent electrode strings 311.

Optionally, in some embodiments, the first through holes 51 communicate with the clearance 53, one of the electrode strings 311 is arranged in each of the first through holes 51, and each of the electrode strings 311 includes at least one electrically-connected sub-cathode 301. The multiple electrode strings 311 are spaced in a direction intersecting with an extension direction of the electrode strings 311, and the multiple electrode strings 311 of each cathode metal layer 31 are electrically connected. In the embodiment of FIG. 3, the cathode metal layers 31 have a comb structure, and in other embodiments, the cathode metal layers 31 may alternatively have another structure.

Optionally, in some embodiments, each of the touch induction electrodes 50 includes a first touch part 52 and multiple spaced second touch parts 54, and the first touch part 52 is connected to each of the second touch parts 54;

and the first through holes 51 are formed between the multiple second touch parts 54. In the embodiment of FIG. 3, the touch induction electrodes 50 have a comb structure. The multiple second touch parts 54 of the touch induction electrode 50 are alternately arranged with the multiple electrode strings 311 of the cathode metal layer 31. That is, the touch induction electrodes 50 and the cathode metal layers 31 form an interdigital structure. In other embodiments, the touch induction electrodes 50 may alternatively have another structure.

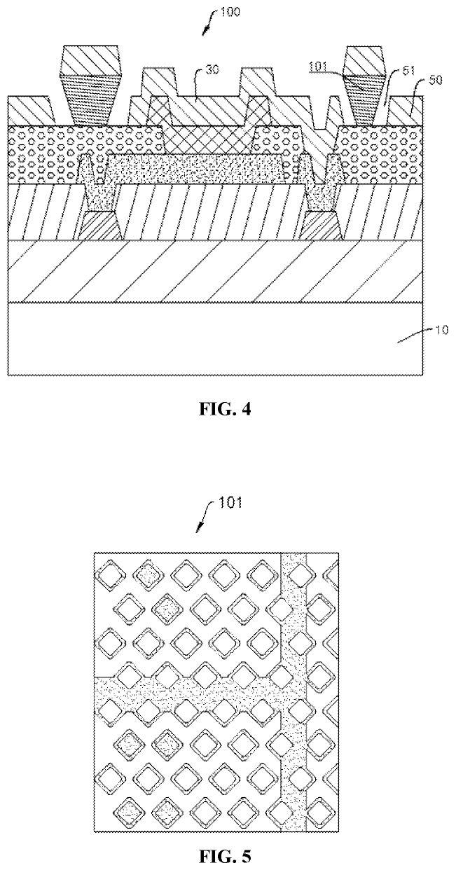

Referring to FIG. 4 and FIG. 5, in some embodiments, the insulating part is multiple insulating spacers 101, and the spacers 101 are located in the first through holes 51 and surround the cathode metal layers 31 to space the cathode metal layers 31 from the touch induction electrodes 50. Gaps are formed between the spacers 101 and the cathode metal layers 31 and between the spacers 101 and the touch induction electrodes 50, and an area of a surface of each of the spacers 101 that is adjacent to the substrate 10 is smaller than an area of a surface of the spacer 101 that faces away from the substrate 10. In this way, when the cathode metal layers 31 and the touch induction electrodes 50 are prepared, a part of a conductive material deposited inside the spacers 101 (the cathode metal layers 31) is spaced from a part of the conductive material deposited outside the spacers 101 (the touch induction electrodes 50), thereby omitting the step of etching the entire metal layer and simplifying a preparation process.

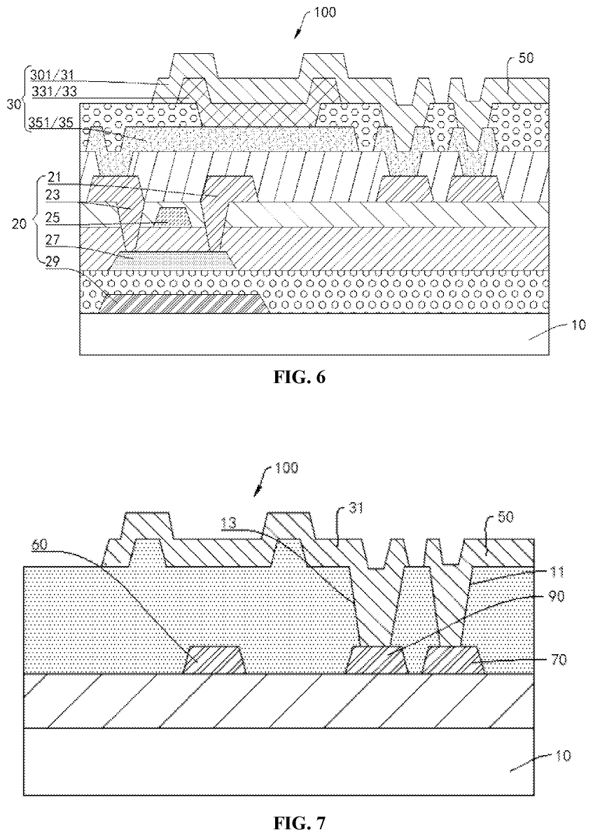

Referring to FIG. 6, the touch display panel 100 according to the embodiment of the present application further includes drive circuits 20, where the drive circuits 20 are located between the substrate 10 and the light-emitting unit layer 30, and is configured to drive the light-emitting unit layer 30 to emit light of different colors.

Specifically, the drive circuits 20 each includes thin-film transistors arranged in an array, and the thin-film transistors each include a source 21, a drain 23, a gate 25 and an active layer 27. The source 21 and the drain 23 are spaced at the same layer, and are separately connected to the active layer 27. The drain 23 or the source 21 is electrically connected to the anode 351 of the light-emitting unit layer 30, the gate 25 and the active layer 27 are insulated from each other at different layers, and the gate 25 is configured to connect to a gate signal. Specifically, the thin-film transistors may have a top gate structure or a bottom gate structure. When the thin-film transistors have the top gate structure, the thin-film transistors each further include a light shielding layer 29. The light shielding layer 29 is located between the substrate 10 and the active layer 27, and is configured to prevent light from entering the active layer 27 from a side of the substrate 10 that faces away from the drive circuits 20 and affecting signals of the drive circuits 20.

Optionally, the source 21, the drain 23 and the gate 25 may be, but are not limited to, metals such as titanium (Ti), aluminum (Al), molybdenum (Mo), copper (Cu) and gold (Au) or metal alloys, respectively, or the like.

Optionally, the active layer 27 may be, but is not limited to, a semiconductor layer such as amorphous silicon (a-Si), polysilicon (p-Si) or a metal oxide, or the like.

Referring to FIG. 7, in some embodiments, the touch display panel 100 according to the present application further includes metal wires 60, where the metal wires 60 are located between the substrate 10 and the cathode metal layers 31. The metal wires 60 may be arranged at the same layer as any metal layer between the substrate 10 and the cathode metal layers 31, or may be located in any insulating layer between the substrate 10 and the cathode metal layers 31, i.e., a single layer of metal wires 60 may be arranged between the substrate 10 and the cathode metal layers 31.

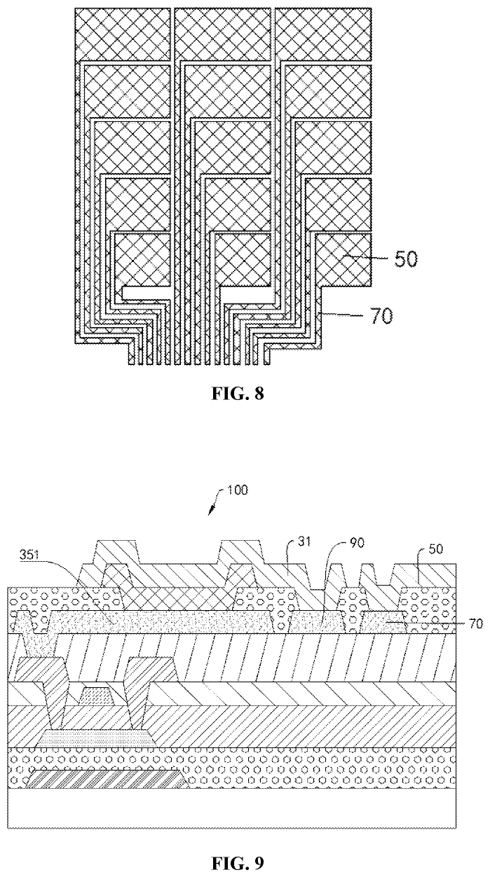

Referring to FIG. 1, FIG. 7 and FIG. 8, the touch display panel 100 according to the embodiments of the present application further includes multiple touch signal lines 70, where the touch signal lines 70 are electrically connected to the touch induction electrodes 50.

As shown in FIG. 8, in some embodiments, the touch signal lines 70 and the cathode metal layers 31 are arranged at the same layer and insulated from each other, and the touch signal lines 70 are located in clearance 53.

As shown in FIG. 1 and FIG. 7, in some other embodiments, the touch signal lines 70 and the touch induction electrodes 50 are arranged at different layers, and an insulating layer is arranged between the touch signal lines 70 and the touch induction electrodes 50; the insulating layer is provided with a second through hole 11, and the touch signal lines 70 are electrically connected to the touch induction electrodes 50 by filling the second through hole 11 with a conductive material, such as a material the same as a material of the cathode metal layers 31.

Specifically, the conductive material may be the same as a material of a metal layer between the touch signal lines 70 and the touch induction electrodes 50, i.e., a material formed at the same time as the metal layer and used for filling the metal layer when another metal layer between the touch signal lines 70 and the touch induction electrodes 50 is prepared. In addition, another metal material may alternatively be used for filling.

As shown to FIG. 1, in some embodiments, the second through hole 11 includes a first hole position 111 and a second hole position 113, the first hole position 111 is filled with a first conductive material, and the second hole position 113 is filled with a second conductive material. The first conductive material is electrically connected to the touch signal lines 70 and the second conductive material, and the second conductive material is electrically connected to the first conductive material and the touch induction electrodes 50. For example, when the touch signal lines 70 are arranged at the same layer as the source 21, the drain 23, the gate 25, the light shielding layer 29 or any metal layer between the substrate 10 and the anodes 351, the first conductive material may be the same as a material of the anodes 351, and the second conductive material may be the same as the material of the cathode metal layers 31. That is, the first hole position 111 is filled with a metal of the anodes 351 when the anodes 351 are prepared, and the second hole position 113 is filled with a metal of the cathode metal layers 31 when the cathode metal layers 31 are prepared.

Referring to FIG. 7 again, in some embodiments, the touch signal lines 70 and the metal wires 60 are arranged at the same layer and insulated from each other. That is, the touch signal lines 70 and the metal wires 60 are formed in the same process or process step. For example, an entire metal layer is formed first, and then the touch signal lines 70 and the metal wires 60 are formed through photoetching.

Referring to FIG. 9, in some embodiments, the touch signal lines 70 and the anodes 351 are arranged at the same layer and insulated from each other. That is, the touch signal lines 70 and the anodes 351 are formed in the same process or process step. For example, an entire metal layer is formed firstly, and then the touch signal lines 70 and the anodes 351 are formed through photoetching.

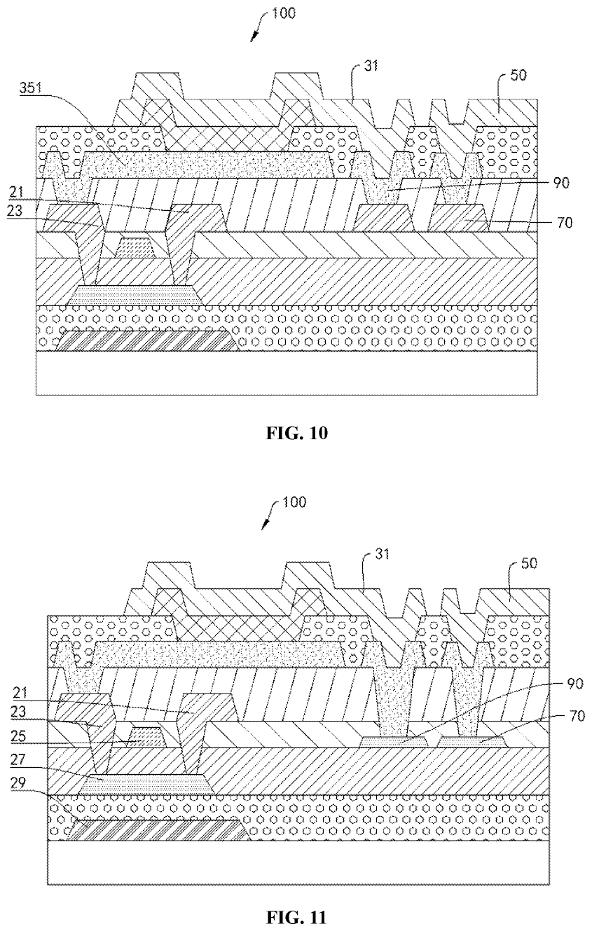

Referring to FIG. 10, in some embodiments, the touch signal lines 70 are arranged at the same layer as the source 21 and the drain 23 and insulated from the source 21 and the drain 23, respectively. That is, the touch signal lines 70 and the source 21 and the drain 23 are formed in the same process or process step. For example, an entire metal layer is formed firstly, and then the touch signal lines 70, the source 21 and the drain 23 are formed through photoetching.

Referring to FIG. 11, in some embodiments, the touch signal lines 70 and the gate 25 are arranged at the same layer and insulated from each other. That is, the touch signal lines 70 and the gate 25 are formed in the same process or process step. For example, an entire metal layer is formed firstly, and then the touch signal lines 70 and the gate 25 are formed through photoetching.

Referring to FIG. 12, in some embodiments, when the thin-film transistors have a top gate structure, the touch signal lines 70 and the light shielding layer 29 are arranged at the same layer and insulated from each other. That is, the touch signal lines 70 and the light shielding layer 29 are formed in the same process or process step. For example, an entire metal layer is formed firstly, and then the touch signal lines 70 and the light shielding layer 29 are formed through photoetching.

Referring to FIG. 1 again, the touch display panel 100 according to the embodiment of the present application further includes multiple cathode lines 90, where the cathode lines 90 are electrically connected to at least one of the cathode metal layers 31; and the cathode lines 90 are located in the first through holes 51, or the clearance 53, or both.

Referring to FIG. 3 again, in some embodiments, the cathode lines 90 and the cathode metal layers 31 are arranged at the same layer and insulated from each other, and the cathode lines 90 are located in the clearance 53.

Referring to FIG. 1 again, in some embodiments, the cathode lines 90 and the cathode metal layers 31 are arranged at different layers, and an insulating layer is arranged between the cathode lines 90 and the cathode metal layers 31; the insulating layer is provided with a third through hole 13, and the cathode lines 90 are electrically connected to the cathode metal layers 31 by filling the third through hole 13 with a conductive material.

Specifically, the conductive material may be the same as a material of a metal layer between the cathode lines 90 and the cathode metal layers 31, i.e., a material formed at the same time as the metal layer and used for filling the metal layer when another metal layer between the cathode lines 90 and the cathode metal layers 31 is prepared. In addition, another metal material may alternatively be used for filling.

In some embodiments, the third through hole 13 includes a third hole position 131 and a fourth hole position 133, the third hole position 131 is filled with a first conductive material, and the fourth hole position 133 is filled with a second conductive material. The first conductive material is electrically connected to the cathode lines 90 and the second conductive material, and the second conductive material is electrically connected to the first conductive material and the touch induction electrodes 50. For example, when the cathode lines 90 are arranged at the same layer as the source 21, the drain 23, the gate 25, the light shielding layer 29 or any metal layer between the substrate 10 and the anodes 351, the first conductive material may be the same as a material of the anodes 351, and the second conductive material may be the same as the material of the cathode metal layers 31. That is, the third hole position 131 is filled with a metal of the anodes 351 when the anodes 351 are prepared, and the fourth hole position 133 is filled with a metal of the cathode metal layers 31 when the cathode metal layers 31 are prepared.

Referring to FIG. 7 again, in some embodiments, the cathode lines 90 and the metal wires 60 are arranged at the same layer and insulated from each other. That is, the cathode lines 90 and the metal wires 60 are formed in the same process or process step. For example, an entire metal layer is formed firstly, and then the cathode lines 90 and the metal wires 60 are formed through photoetching.

Referring to FIG. 9 again, in some embodiments, the cathode lines 90 and the anodes 351 are arranged at the same layer and insulated from each other. That is, the cathode lines 90 and the anodes 351 are formed in the same process or process step. For example, an entire metal layer is formed firstly, and then the cathode lines 90 and the anodes 351 are formed through photoetching.

Referring to FIG. 10 again, in some embodiments, the cathode lines 90 are arranged at the same layer as the source 21 and the drain 23 and insulated from the source 21 and the drain 23. That is, the cathode lines 90 and the source 21 and the drain 23 are formed in the same process or process step. For example, an entire metal layer is formed firstly, and then the cathode lines 90, the source 21 and the drain 23 are formed through photoetching.

Referring to FIG. 11 again, in some embodiments, the cathode lines 90 and the gate 25 are arranged at the same layer and insulated from each other. That is, the cathode lines 90 and the gate 25 are formed in the same process or process step. For example, an entire metal layer is formed first, and then the cathode lines 90 and the gate 25 are formed through photoetching.

Referring to FIG. 12 again, in some embodiments, when the thin-film transistors have a top gate structure, the cathode lines 90 and the light shielding layer 29 are arranged at the same layer and insulated from each other. That is, the cathode lines 90 and the light shielding layer 29 are formed in the same process or process step. For example, an entire metal layer is formed first, and then the cathode lines 90 and the light shielding layer 29 are formed through photoetching.

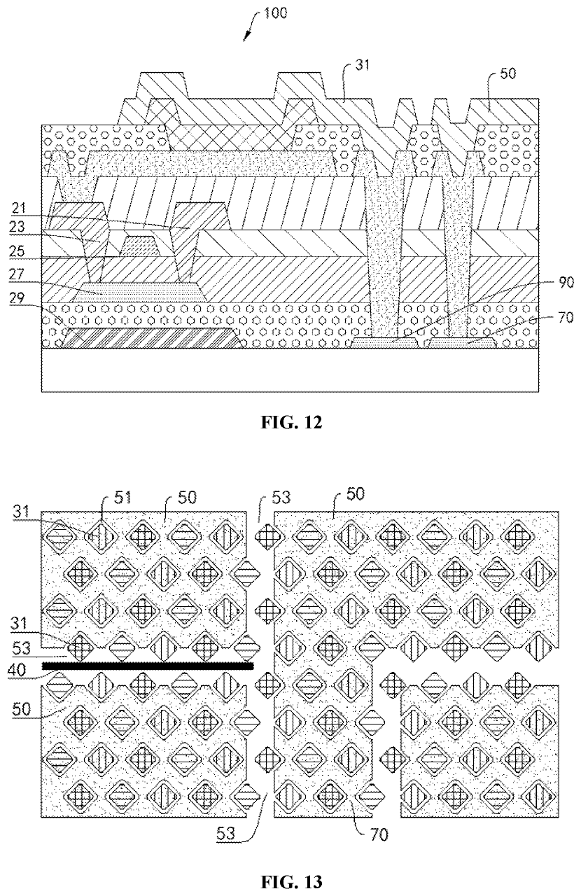

Referring to FIG. 13, in some embodiments, the touch display panel 100 according to the embodiments of the present application further includes multiple display signal lines 40, where the display signal lines 40 are opposite to the clearance 53. The display signal lines 40 are arranged in the clearance 53, which prevents capacitive crosstalk between the display signal lines 40 and the touch induction electrodes 50.

Specifically, the display signal lines 40 each may be a display data signal line or a display scanning signal line.

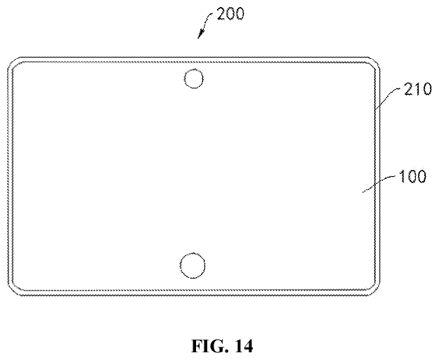

Referring to FIG. 14, an embodiment of the present application further provides an electronic device 200, including:

a device body 210; and

the touch display panel 100 according to the embodiment of the present application, where the touch display panel 100 is arranged on the device body 210.

The electronic device 200 according to the present application includes, but is not limited to, devices with a display function such as a display, a computer, a television set, a tablet computer, a mobile phone, an e-reader, a smartwatch with a display screen, a smart bracelet and a player with a display screen.

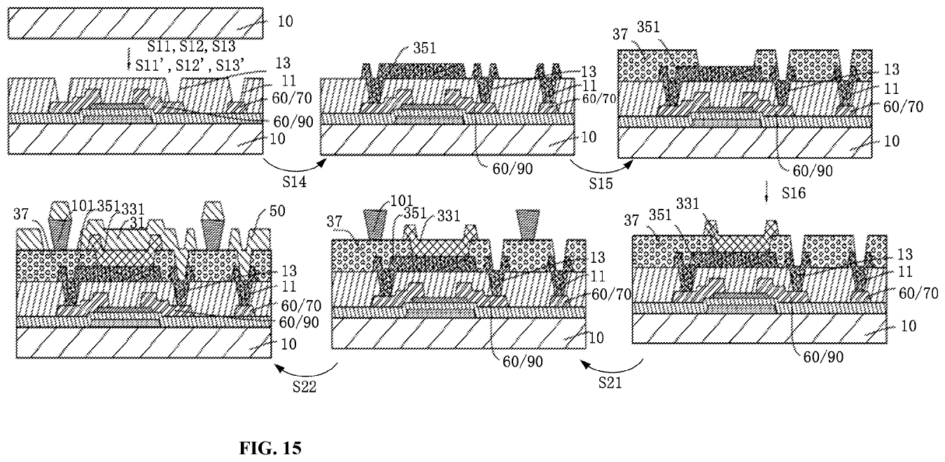

Referring to FIG. 15, an embodiment of the present application further provides a manufacturing method for the touch display panel 100, including the following steps.

S1: Form a driver layer on one side of a substrate 10, and form a light-emitting structure layer on a side of the driver layer that faces away from the substrate 10.

Specifically, the driver layer includes, but is not limited to, a source 21, a drain 23, a gate 25, an active layer 27, metal wires serving as touch signal lines 70 or cathode lines 90, and an insulating layer configured to space and insulate the components from each other. When thin-film transistors have a top gate structure, the driver layer further includes a light shielding layer 29.

Specifically, the light-emitting structure layer includes, but is not limited to, a pixel definition layer 37, anodes 351 and light-emitting parts 331. The pixel definition layer 37 is arranged on a side of each of the driver layer and the anodes 351 that faces away from the substrate 10, and covers the driver layer and the anodes 351.

Optionally, in some embodiments, the forming a driver layer on one side of a substrate 10 specifically includes the following steps.

S11: Form drive circuits 20 and metal wires 60 on the side of the substrate 10, where the drive circuits 20 includes a source 21, a drain 23 and a gate 25, or a source 21, a drain 23, a gate 25 and a light shielding layer 29, the metal wires 60 are arranged at the same layer as and insulated from the source 21, the drain 23, the gate 25 and the light shielding layer 29, and the metal wires 60 are touch signal lines 70.

S12: Form an insulating layer on the metal wires 60.

S13: Form a second through hole 11 in the insulating layer, and fill the second through hole 11 with a conductive material.

Optionally, in some other embodiments, the forming a driver layer on one side of a substrate 10 specifically includes the following steps.

S11′: Form drive circuits 20 and metal wires 60 on the side of the substrate 10, where the drive circuits 20 includes a source 21, a drain 23 and a gate 25, or a source 21, a drain 23, a gate 25 and a light shielding layer 29, the metal wires 60 are arranged at the same layer as and insulated from the source 21, the drain 23, the gate 25 or the light shielding layer 29, and the metal wires 60 are cathode lines 90.

S12′: Form an insulating layer on the metal wires 60.

S13′: Form a third through hole 13 in the insulating layer, and fill the third through hole 13 with a conductive material.

Optionally, in some other embodiments, the forming a light-emitting structure layer on a side of the driver layer that faces away from the substrate 10 specifically includes the following steps.

S14: Form multiple anodes 351 arranged in an array on the side of the driver layer that faces away from the substrate 10.

Optionally, in some embodiments, multiple touch signal lines 70 are further formed in a process of forming the multiple anodes 351 arranged in an array, where the multiple touch signal lines 70 and the anodes 351 are arranged at the same layer and insulated from each other.

Optionally, in some embodiments, multiple cathode lines 90 are further formed in a process of forming the multiple anodes 351 arranged in an array, where the multiple cathode lines 90 and the anodes 351 are arranged at the same layer and insulated from each other.

S15: Form a pixel definition layer 37 on the multiple anodes 351 and the side of the driver layer that faces away from the substrate 10, and form multiple openings at positions in the pixel definition layer 37 that correspond to the multiple anodes 351.

S16: Form multiple light-emitting parts 331 arranged in an array in the multiple openings.

S2: Form cathode metal layers 31 and touch induction electrodes 50 on the light-emitting structure layer, where the touch induction electrodes 50 and the cathode metal layers 31 are arranged at the same layer and insulated from each other.

Optionally, the forming cathode metal layers 31 and touch induction electrodes 50 on the light-emitting structure layer specifically includes the following steps.

S21: Form spacers 101 on the light-emitting structure layer.

S22: Form metal layers on the light-emitting structure layer and the spacers 101, where the metal layers are spaced by the spacers 101 in a forming process to form the cathode metal layers 31 and the touch induction electrodes 50. That is, the cathode metal layers 31 and the touch induction electrodes 50 are formed in the same process.

Specifically, the metal layers formed on the spacers 101 are spaced from the cathode metal layers 31 and the touch induction electrodes 50 formed on the light-emitting structure layer.

Optionally, in some embodiments, an area of a surface of each of the spacers 101 that is adjacent to the substrate 10 is smaller than an area of a surface of the spacer 101 that faces away from the substrate 10. This structure with a wide top and a narrow bottom allows the metal layers to be naturally spaced by the spacers 101 to form the cathode metal layers 31 and the touch induction electrodes 50 during the process of forming the metal layers, so as to prevent a subsequent step of etching the metal layers to form the cathode metal layers 31 and the touch induction electrodes 50.

Optionally, in some embodiments, the touch induction electrodes 50 are further electrically connected to the touch signal lines 70 in a process of forming the multiple touch induction electrodes 50.

Optionally, in some embodiments, the cathode metal layers 31 are further electrically connected to the cathode lines 90 in a process of forming the cathode metal layers 31.

For a detailed description of the manufacturing method, reference may be made to the detailed description of the touch display panel 100 according to the above-mentioned embodiment of the present application, which will not be repeated herein.

The above are merely specific implementations of the present application, but the protection scope of the present application is not limited thereto. Any person skilled in the art may easily figure out various equivalent modifications or replacements within the technical scope disclosed in the present application, and these modifications or replacements should fall within the protection scope of the present application. Therefore, the protection scope of the present application should be subject to the protection scope of the claims

What is claimed is:

1. A touch display panel, comprising:
a substrate;
a light-emitting unit layer, wherein the light-emitting unit layer is located on one side of the substrate, and comprises multiple cathode metal layers; and
multiple touch induction electrodes arranged in an array, wherein the touch induction electrodes and the cathode metal layers are arranged at the same layer and insulated from each other, each of the touch induction electrodes is provided with at least one first through hole, a clearance is formed between adjacent two of the touch induction electrodes, and the cathode metal layers are arranged in the first through holes, or the clearance, or both.

2. The touch display panel according to claim 1, wherein the cathode metal layers located in the first through holes are surrounded by the touch induction electrodes and are spaced from the touch induction electrodes by a gap or an insulating part.

3. The touch display panel according to claim 1, further comprising multiple insulating spacers, wherein the spacers are located in the first through holes to space the cathode metal layers from the touch induction electrodes, and an area of a surface of each of the spacers that is adjacent to the substrate is smaller than an area of a surface of the spacer that faces away from the substrate.

4. The touch display panel according to claim 1, wherein the at least one first through hole is spaced from one another, and one cathode metal layer is arranged in each of the first through holes.

5. The touch display panel according to claim 1, wherein the cathode metal layers and the touch induction electrodes are staggered.

6. The touch display panel according to claim 5, wherein the cathode metal layers each comprise multiple electrically-connected electrode strings, and the touch induction electrodes each are arranged between adjacent electrode strings.

7. The touch display panel according to claim 6, wherein the first through holes communicate with the clearance, one of the electrode strings is arranged in each of the first through holes, and each of the electrode strings comprises at least one electrically-connected sub-cathode.

8. The touch display panel according to claim 1, further comprising multiple touch signal lines, wherein the touch signal lines are electrically connected to the touch induction electrodes; the touch signal lines and the cathode metal layers are arranged at the same layer and insulated from each other, and the touch signal lines are located in the clearance.

9. The touch display panel according to claim 1, further comprising multiple touch signal lines, wherein the touch signal lines are electrically connected to the touch induction electrodes, the touch signal lines and the touch induction electrodes are arranged at different layers, and an insulating layer is arranged between the touch signal lines and the touch induction electrodes; the insulating layer is provided with a second through hole, and the touch signal lines are electrically connected to the touch induction electrodes by filling the second through hole with a conductive material.

10. The touch display panel according to claim 1, further comprising multiple cathode lines, wherein the cathode lines each are electrically connected to at least one of the cathode metal layers; and the cathode lines are located the first through holes, or the clearance, or both.

11. The touch display panel according to claim 1, further comprising multiple cathode lines, wherein the cathode lines each are electrically connected to at least one of the cathode metal layers; the cathode lines and the cathode metal layers are arranged at different layers, and an insulating layer is arranged between the cathode lines and the cathode metal layers; the insulating layer is provided with a third through hole, and the cathode lines are electrically connected to the cathode metal layers by filling the third through hole with a conductive material.

12. An electronic device, comprising:
a device body; and
a touch display arranged on the device body, wherein the touch display comprises:
a substrate;
a light-emitting unit layer, wherein the light-emitting unit layer is located on one side of the substrate, and comprises multiple cathode metal layers; and
multiple touch induction electrodes arranged in an array, wherein the touch induction electrodes and the cathode metal layers are arranged at the same layer and insulated from each other, each of the touch induction electrodes is provided with at least one first through hole, a clearance is formed between adjacent two of the touch induction electrodes, and the cathode metal layers are arranged in the first through holes, or the clearance, or both.

13. A manufacturing method for a touch display panel, comprising:
forming a driver layer on one side of a substrate, and forming a light-emitting structure layer on a side of the driver layer that faces away from the substrate; and
forming cathode metal layers and touch induction electrodes on the light-emitting structure layer, wherein the touch induction electrodes and the cathode metal layers are arranged at the same layer and insulated from each other.

14. The manufacturing method for a touch display panel according to claim 13, wherein the cathode metal layers and the touch induction electrodes are formed in the same process.

15. The manufacturing method for a touch display panel according to claim 13, wherein the forming cathode metal layers and touch induction electrodes on the light-emitting structure layer specifically comprises:
forming spacers on the light-emitting structure layer; and
forming metal layers on the light-emitting structure layer and the spacers, wherein the metal layers are spaced by the spacers in a forming process to form the cathode metal layers and the touch induction electrodes, respectively.

16. The manufacturing method for a touch display panel according to claim 15, wherein an area of a surface of each of the spacers that is adjacent to the substrate is smaller than an area of a surface of the spacer that faces away from the substrate.

17. The manufacturing method for a touch display panel according to claim 15, wherein the metal layers formed on the spacers are spaced from the cathode metal layers and the touch induction electrodes formed on the light-emitting structure layer, respectively.

18. The manufacturing method for a touch display panel according to claim 13, wherein the forming a driver layer on one side of the substrate specifically comprises:
forming drive circuits and metal wires on the side of the substrate, wherein the drive circuits each comprise a source, a drain and a gate, or the drive circuits each comprise a source, a drain, a gate and a light shielding layer, the metal wires are arranged at the same layer as and insulated from the source, the drain, the gate and the light shielding layer, respectively, and the metal wires are touch signal lines;
forming an insulating layer on the metal wires; and
forming a second through hole in the insulating layer, and filling the second through hole with a conductive material.

19. The manufacturing method for a touch display panel according to claim 13, wherein the forming a driver layer on one side of the substrate specifically comprises:
forming drive circuits and metal wires on the side of the substrate, wherein the drive circuits each comprise a source, a drain and a gate, or he drive circuits each comprise a source, a drain, a gate and a light shielding layer, the metal wires are arranged at the same layer as and insulated from the source, the drain, the gate and the light shielding layer, respectively and the metal wires are cathode lines;
forming an insulating layer on the metal wires; and
forming a third through hole in the insulating layer, and filling the third through hole with a conductive material.

20. The manufacturing method for a touch display panel according to claim 13, wherein the forming a light-emitting structure layer on a side of the driver layer that faces away from the substrate specifically comprises:
forming multiple anodes arranged in an array on the side of the driver layer that faces away from the substrate;
forming a pixel definition layer on the multiple anodes and the side of the driver layer that faces away from the substrate, and forming multiple openings at positions in the pixel definition layer that correspond to the multiple anodes; and
forming multiple light-emitting parts arranged in an array in the multiple openings, respectively.
